(19) United States
(12) Patent Application Publication
(10) Pub. No.: US 2010/0326499 A1
(43) Pub. Date: Dec. 30, 2010

(54) SOLAR CELL WITH ENHANCED EFFICIENCY

(75) Inventor: Yue Liu, Plymouth, MN (US)

Correspondence Address: HONEYWELL/CST;Patent Services, 101 Columbia Road, P.O. Box 2245, Morristown, NJ, 07962-2245, US

(73) Assignee: HONEYWELL INTERNATIONAL INC., Morristown, NJ (US)

(21) Appl. No.: 12/814,878

(22) Filed: Jun. 14, 2010

Related U.S. Application Data
(60) Provisional application No. 61/222,031, filed on Jun. 30, 2009.

(51) Int. Cl. H01L 31/00

(52) U.S. Cl. 136/252

(57) ABSTRACT

Solar cells and methods for manufacturing solar cells are disclosed. An example solar cell includes a substrate, and an electron conductor layer situated adjacent the substrate. The electron conductor layer may form a pattern of projections with one or more gaps between the projections. An active layer may be situated in the gaps between the projections, and coupled to the electron conductor layer. A hole conductor may be coupled to the active layer. The hole conductor layer may partially or fully fill in the gaps between the projections. The projections may be nano-pillars, nano-tubes, nano-wires, or any other suitable projections, as desired. In some cases, the aspect ratio of the projections may be greater than 2:1, 5:1 or more.

This application claims priority under 35 U.S.C. §119(e) to U.S. Provisional Patent Application No. 61/222,031, filed on Jun. 30, 2009, the entire disclosure of which is incorporated herein by reference.

### TECHNICAL FIELD

The disclosure relates generally to solar cells. More particularly, the disclosure relates to solar cells with enhanced efficiency and methods for manufacturing the same.

### BACKGROUND

A wide variety of solar cells have been developed for converting light into electricity. Of the known solar cells, each has certain advantages and disadvantages. There is an ongoing need to provide alternative solar cells with enhanced efficiency, as well as methods for manufacturing solar cells.

### SUMMARY

The disclosure relates generally to solar cells with enhanced efficiency, and methods for manufacturing solar cells. An example solar cell may include a substrate. An electron conductor layer may be situated adjacent the substrate. The electron conductor layer may form a pattern of projections with one or more gaps between the projections. An active layer may be situated in the gaps between the projections, and coupled to the electron conductor layer. A hole conductor may be coupled to the active layer. In some embodiments, the active layer may only partially fill in the gaps between the projections. When so provided, the hole conductor may partially or completely fill in the gaps, as desired. In other embodiments, the active layer may fill in the gaps between the projections. In some instances, the pattern of projections may form be a structured or random array or pattern, as desired. The projections may be nano-pillars, nano-tubes, nano-wires, or any other suitable projections, as desired. In some cases, the aspect ratio of the projections may be greater than 2:1, 5:1 or more.

The above summary of some embodiments is not intended to describe each disclosed embodiment or every implementation of the present invention. The Figures, and Detailed Description, which follow, more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1 is a schematic cross-sectional side view of an illustrative solar cell;

FIG. 2 is a schematic cross-sectional side view of another illustrative solar cell;

FIG. 3 is a schematic cross-sectional side view of another illustrative solar cell; and

FIG. 4 is a schematic cross-sectional side view of another illustrative solar cell.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DESCRIPTION

For the following defined terms, these definitions shall be applied, unless a different definition is given in the claims or elsewhere in this specification.

All numeric values are herein assumed to be modified by the term “about,” whether or not explicitly indicated. The term “about” generally refers to a range of numbers that one of skill in the art would consider equivalent to the recited value (i.e., having the same function or result). In many instances, the terms “about” may include numbers that are rounded to the nearest significant figure.

The recitation of numerical ranges by endpoints includes all numbers within that range (e.g. 1 to 5 includes 1, 1.5, 2, 2.75, 3, 3.80, 4, and 5).

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The following description should be read with reference to the drawings. The drawings, which are not necessarily to scale, depict an illustrative embodiments and are not intended to limit the scope of the invention.

A wide variety of solar cells (which also may be known as photovoltaics and/or photovoltaic cells) have been developed for converting sunlight into electricity. Some example solar cells include a layer of crystalline silicon. Second and third generation solar cells often utilize a thin film of photovoltaic material (e.g., a “thin” film) deposited or otherwise provided on a substrate. These solar cells may be categorized according to the photovoltaic material deposited. For example, inorganic thin-film photovoltaics may include a thin film of amorphous silicon, microcrystalline silicon, CdS, CdTe, Cu₂S, copper indium diselenide (CIS), copper indium gallium diselenide (CIGS), etc. Organic thin-film photovoltaics may include a thin film of a polymer or polymers, bulk heterojunctions, ordered heterojunctions, a fullerence, a polymer/fullerence blend, photosynthetic materials, etc. These are only examples.

Efficiency is an important performance metric of the design and production of photovoltaics. One factor that may correlate to efficiency is the active layer thickness. A thicker active layer is typically able to absorb more light. This may desirably improve efficiency of the cell. However, thicker active layers often lose more charges due to higher internal resistance and/or increased recombination, which reduces efficiency. Thinner active layers may have less internal resistance and/or less recombination, but typically do not absorb light as effectively as thicker active layers.

The solar cells disclosed herein are designed to be more efficient by, for example, increasing the light absorbing ability of the active layer while reducing internal resistance and/or recombination. The methods for manufacturing photovoltaics and/or photovoltaic cells disclosed herein are aimed at producing more efficient photovoltaics at a lower cost.

At least some of the solar cells disclosed herein utilize an active layer that includes a polymer or polymers. For example, as least some of the solar cells disclosed herein include an active layer that includes a bulk heterojunction (BHJ) using conductive polymers. Solar cells that include a BHJ based on conductive polymers may be desirable for a number of reasons. For example, the costs for manufacturing a BHJ based on conductive polymers may be lower than the costs of manufacturing active layers of other types of solar cells. This may be due to the lower cost associated with the materials used to make such a BHJ (e.g., polymers) solar cell, as well as possible use of roll-to-roll and/or other efficient manufacturing techniques.

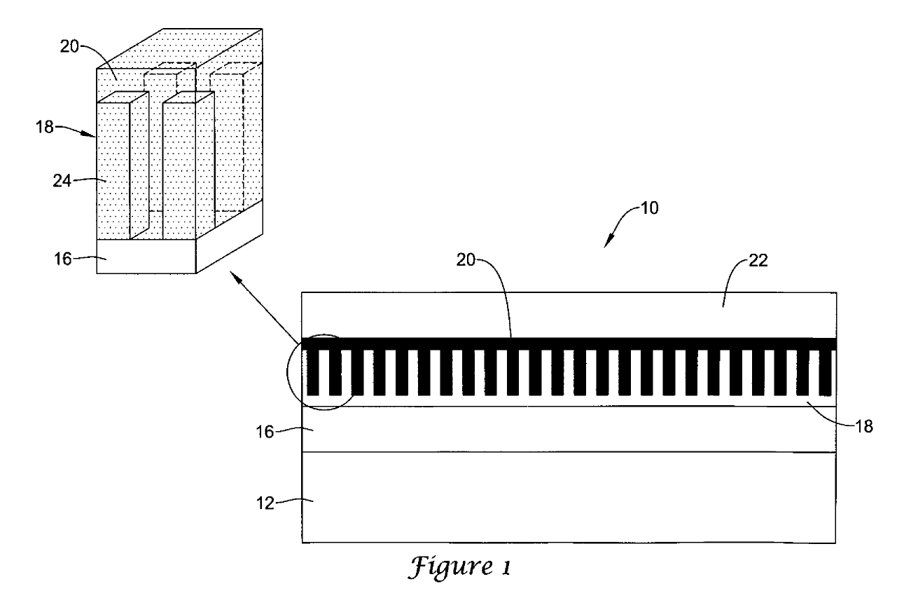

FIG. 1 is a schematic cross-sectional side view of an illustrative solar cell 10. In the illustrative embodiment, solar cell 10 include a substrate 12, with a first electrode (e.g., a cathode or positive electrode) 16 coupled relative to or otherwise disposed on substrate 12. A layer of material 18 may be electrically coupled to or otherwise disposed on electrode 16. The layer of material 18 may be formed from a material that is suitable for accepting holes from active layer 20 of the solar cell 10 (e.g. hole conducting layer). The layer of material 18 may include or be formed so as to take the form of a structured pattern or array or projections, such as a nano-pillar array 18. An active layer 20 may be coupled to or otherwise be disposed over and “fill in” the structured pattern or array in layer 18. Solar cell 10 may also include a second electrode 22 (e.g., an anode or negative electrode) that is electrically coupled to active layer 20.

In some embodiments, the polarity of the electrodes may be reversed. For example, first electrode 16 may be an anode and second electrode 22 may be a cathode. Consequently, first electrode 16 may accept electrons from active layer 20, and layer 18 may be formed from a material that is suitable for accepting electrons (e.g. electron conducting layer) from active layer 20. Also, the second electrode 22 may be formed from a material that is suitable for accepting holes from active layer 20 (e.g. hole conducting layer). In other solar cells, including those disclosed below, the polarity may also be reversed with respect to the manner in which they are described, to the extent applicable.

Substrate 12, when provided, may be made from a number of different materials including polymers, glass, and/or transparent materials. In one example, substrate 12 may include polyethylene terephthalate, polyimide, low-iron glass, or any other suitable material, or combination of suitable material. The first electrode 16 may include, fluorine-doped tin oxide, indium tin oxide, Al-doped zinc oxide, any other suitable conductive inorganic element or compound, conductive polymer, and/or other electrically conductive material, or any other suitable material as desired. In some cases, the first electrode 16 may be considered the substrate. In some embodiments, solar cell 10 may lack substrate 12 and, instead, may rely on another structure to form a base layer, if desired.

Layer 18 may be an imprintable layer. In one example, layer 18 may include a material suitable for imprinting a pattern in the layer 18, such as a polymer. When a polymer is used, it is contemplated that a variety of different polymers may be suitable including, for example, polyimide, poly(3,4-ethylenedioxythiophene) poly(styrenesulfonate) (PEDOT:PSS), or any other suitable polymer or polymer combination, as desired. PEDOT:PSS has the following structure:

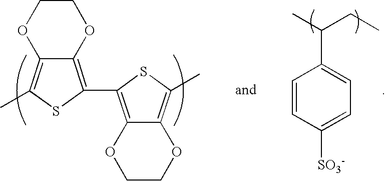

In some cases, layer 18 may have an energy band gap relative to the active layer 20 that is suitable for accepting holes from the active layer 20. In some cases, layer 18 may be nano-imprinted or otherwise formed with a nano-pillar array.

In an illustrative embodiment, active layer 20 may include one or more polymers or polymer layers. In one example, active layer 20 may include an interpenetrating network of electron donor and electron acceptor polymers. In some embodiments, active layer 20 may include an interpenetrating network of poly-3-hexylthiophen (P3HT) and [6,6]-phenyl-C61-butyric acid methyl ester (PCBM). P3HT is a photoactive polymer. Consequently, the P3HT material may absorb light and generate electron-hole pairs (excitons). While not being bound by theory, it is believed that as light is absorbed by active layer 20, an exciton is generated that diffuses to a nearby P3HT/PCBM interface within the active layer 20, where the electron-hole pair disassociates. The electrons may then be injected into the PCBM, which may have an energy band gap relative to P3HT so as to readily accept electrons from the P3HT material. The electrons may then be transported along the PCBM chain to the second electrode 22. The holes may be transported within the P3HT to a nearby pillar of, for example, a nano-pillar array in layer 18 and ultimately to the first electrode 16. As indicated above, and in some embodiments, layer 18 may have an energy band gap relative to the active layer 20 that is suitable for accepting holes from the active layer 20.

It is contemplated that other materials may be used, as desired for active layer 20. For example, in some embodiments, active layer 20 may include poly[2,7-(9,9-di-n-octyl-silafluorene)-alt-5,5″-(4′,7′-di-2-thienyl-2′,1′,3′-benzothiadiazole)] (PSiF-DBT), PCBM, or a blend of PSiF-DBT and PCBM.

The thickness of the active layer can have a significant effect on the efficiency of a solar cell. The pattern in layer 18 may decrease the effective thickness of the active layer 20, which may increase the efficiency of the solar cell. As indicated above, and while not limited to such, the pattern in layer 18 may be a nano-pillar array that includes a plurality of nano-pillars or projections 24 that extend upward. In an illustrative embodiment, nano-pillars 24 may have a width on the order of about 40-60 nm, or about 50 nm, and a spacing on the order of 10-80 nm, or about 25 nm. In some embodiments, nano-pillars 24 may have a substantially squared shape as shown so that the width in uniform in perpendicular directions. In other embodiments, nano-pillars 24 may be cylindrical in shape and, thus, may have a uniform or non-uniform width in all directions. However, it is contemplated that the nano-pillars may have any suitable shape including honeycomb shaped, star shaped, or any other shape, as desired. The nano-pillars 24 may be arranged so that adjacent nano-pillars 24 are spaced so as to form wells, channels or gaps therebetween. In some cases, the height of the nano-pillars 24 relative to their width may result in a relatively large aspect ratio, but this is not required. For example, the height of the nano-pillars 24 may be about 200-400 nm, or about 250 nm, which may result in about a 5:1 aspect ratio or more. It is contemplated that active layer 20 may be provided in the wells, channels or gaps between the nano-pillars 24, as shown. That is, in some embodiments, the active layer 20 may fill (fully or partially) the forest of nano-pillars 24. In some cases, the active layer 20 may be spin coated on the nano-pillars 24 to help fill in the wells and channels.

In general, the distance between adjacent nano-pillars 24 may be configured so as to improve the efficiency of the solar cell 10. For example, the distance between adjacent nano-pillars 24 may be set to about 10-80 nm or less, or set to about 25 nm or less. For example, with a pattern of square nano-pillars 24 spaced at 25 nm, the furthest distance an exciton must travel within the active layer to an adjacent nano-pillar 24 is about 35 nm. This travel distance can define the worst case “effective” thickness of the active layer 20. Note, in this illustrative embodiment, many of the holes may travel laterally though the active layer to an adjacent nano-pillar 24, rather than vertically down to layer 18. In comparison, typical solar cells that utilize a BHJ may have a planar active layer with a thickness of about 100-200 nm. When so provided, the worst case “effective” thickness of such an active layer may be 100-200 nm. As can be seen, the effective thickness of the active layer 20 in solar cell 10 may be considerably reduced, which may help increase the efficiency of solar cells 10 by reducing internal resistance and/or recombination within the active layer 20.

While nano-pillars 24 are shown in FIG. 1, it is contemplated that other arrangements or patterns may be used. In general, the structural arrangement of the pattern in layer 18 may be configured to produce a reduced effective thickness of the active layer 20 relative to a simple planar surface, and may include a plurality of projections and/or impressions, be textured, have surface features and/or other irregularities, and/or have other projections (e.g. nano-tubes, nano-wires, etc.) as desired.

It is also noted that the pattern in layer 18 may produce light scattering within the active layer 20 in solar cell 10. Because of this light scattering, more light (photons) may be absorbed by active layer 20. To help increase the light scatter and corresponding absorption of light in the active layer 20, it is contemplated that the height of the pattern in layer 18 relative to the width of the patterned elements may produce a relatively large aspect ratio (e.g. 2:1, 5:1, 10:1 or more). As mentioned above, the aspect ratio of the nano-pillars 24 may be about 5:1, but this is only an example.

An example method for manufacturing solar cell 10 may include providing substrate 12 including a layer 18 that will be imprinted with a pattern. In some cases, a first electrode layer 16 (e.g. ITO) may be provided between substrate 12 and layer 18. In any event, a pattern may be imprinted or otherwise formed in layer 18. Alternatively, the layer 18 may be imprinted and then subsequently attached to a substrate 12 or the first electrode layer 16. In some cases, the substrate 12 may not be used. Forming the pattern in layer 18 may include any of a variety of different methods including, for example, hot embossing, soft lithography, micro-contact imprinting, ultraviolet lithographical imprinting, and the like, or using any other suitable method as desired. In one non-limiting example, a silicon wafer with an array of nano-pillars (e.g., about 50 nm wide and about 250 nm high) may be formed using a suitable technique such as e-beam lithography. A stamp may be formed by casting (e.g. spin coating) a stamp material (e.g., polydimethylsiloxane) onto the wafer and curing the material to form a stamp having an array of nano-pits (e.g., depressions that form the mirror image or inverse of the nano-pillars 24 on the wafer). Layer 18 may be spin-coated onto substrate 12 or the first electrode layer 16 so as to have a suitable thickness (e.g., about 300 nm). The stamp may then be used to imprint layer 18 to form the nano-pillar or other array 24.

Active layer 20 may be disposed on patterned layer 18 using any suitable method. In one example, the materials for active layer 20 (e.g., P3HT/PCBM, PSiF-DBT/PCBM, etc.) may be mixed in a suitable solvent and spin-coated onto patterned layer 18. The spin-coating process may help distribute the active layer 20 throughout the pattern on layer 18, e.g. filling the spaces between nano-pillars 24. The second electrode 22, which may be aluminum or any other suitable material, may be provided over active layer 20 using any suitable method such as e-beam evaporation or sputtering. Such a method may be easily scaled-up, which may make manufacturing of solar cells like solar cell 10 more cost-effective for a variety of applications including applications that use large quantities or sheets of solar cells 10.

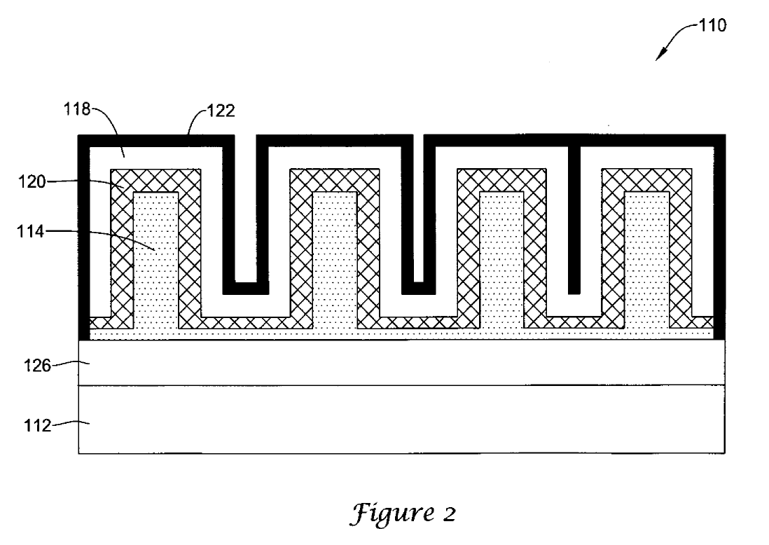

FIG. 2 illustrates another example solar cell 110 that may, in some cases, be similar to other solar cells disclosed herein. Solar cell 110 may include a substrate 112. In at least some embodiments, substrate 112 may include glass or any other suitable material or material combination, as desired. A conductive material or layer 126 may be disposed on substrate 112. In some cases, layer 126 may include fluorine-doped tin oxide glass. Alternatively, solar cell 110 may include a single “substrate” or layer that includes fluorine-doped tin oxide glass or any other suitable material or material combination, as desired.

In the illustrative embodiment, an electron conductor layer 114 is coupled to layer 126. In some cases, electron conductor layer 114 may be a metallic and/or semiconducting material, such as TiO₂ or ZnO. Alternatively, electron conductor layer 114 may be an electrically conducting polymer such as a polymer that has been doped to be electrically conducting and/or to improve its electrical conductivity. In at least some embodiments, electron conductor layer 114 may include an n-type conductor and/or form or otherwise be adjacent to the anode (anode or negative electrode) of cell 110.

Electron conductor layer 114 may be configured as a nanowire or nanotube array. Consequently, electron conductor layer 114 may have an increased surface area similar to layer 18 of cell 10. The precise structure of electron conductor layer 114 may vary. For example, electron conductor layer 114 may include one or more projections and/or impressions, be textured, have an ordered nonporous structure, have surface features and/or other irregularities, and/or have other non-planar features, as desired.

An active layer 120 may be disposed on or otherwise electrically coupled to electron conductor layer 114. Active layer 120 may be similar to other active layers disclosed herein. For example, active layer 120 may include a blend of poly[2,7-(9,9-di-n-octyl-silafluorene)-alt-5,5″-(4′,7′-di-2-thienyl-2′,1′,3′-benzothiadiazole)] (PSiF-DBT) and PCBM. In general, active layer 120 may generally follow or trace electron conductor layer 114. Consequently, active layer 120 may have a structured configuration. In some cases, this may be desirable. For example, the structured configuration of active layer 120 may increase the efficiency of solar cell 110 by, for example, allowing active layer to absorb more photons relative to a planer active layer and/or reducing recombination, as further described above.

A layer 118 may be disposed on or otherwise electrically coupled to active layer 120. In one illustrative embodiment, layer 118 may include polyimide, poly(3,4-ethylenedioxythiophene) poly(styrenesulfonate) (PEDOT:PSS), or any other suitable polymer, polymer combination, or other material, as desired. In some embodiments, layer 118 may generally follow the surface of active layer 120. PEDOT:PSS has the following structure:

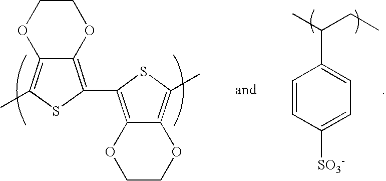

An electrode 122 may be disposed on or otherwise electrically coupled to layer 118. In some embodiments, electrode 122 may generally follow the surface of layer 118, as shown. Electrode 122 may be the positive electrode (e.g., the cathode). In other instances, electrode 122 may be the negative electrode (e.g., the anode).

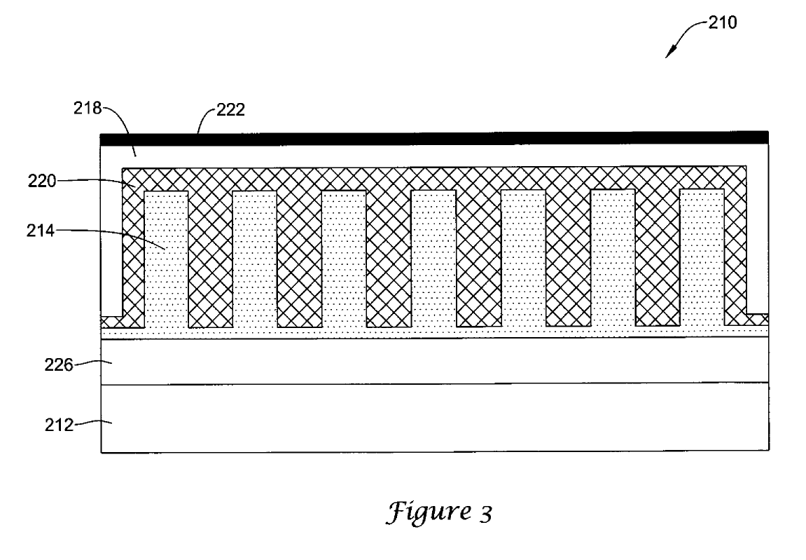

FIG. 3 illustrates another example solar cell 210 that may be similar to other solar cells disclosed herein. Solar cell 210 may include substrate 212, layer 226 coupled to substrate 212, electron conductor layer 214 coupled to layer 226, active layer 220 coupled to electron conductor layer 214, layer 218 coupled to active layer 220, and electrode 222 coupled to layer 218. As in cell 110, substrate 212 may include glass, layer 226 may include fluorine-doped tin oxide glass, electron conductor layer 214 may include TiO₂ or ZnO, active layer 220 may include a blend of poly[2,7-(9,9-di-n-octyl-silafluorene)-alt-5,5″-(4′,7′-di-2-thienyl-2′,1′,3′-benzothiadiazole)] (PSiF-DBT) and PCBM, and layer 218 may include poly(3,4-ethylenedioxythiophene) poly(styrenesulfonate) (PEDOT:PSS). These are only examples. It is contemplated that other materials may be used for these layers including any of those materials disclosed herein.

In cell 210, electron conductor layer 214 may, in some cases, be structured as a nano-pillar, nano-wire, nano-tube or other structured or random array or pattern, and active layer 220 may “fill in” (partially or fully) the structured arrangement of electron conductor layer 214. In other words, gaps may be formed between adjacent nano-pillars, nano-wires or nano-tubes, and active layer 210 may fill in (partially or fully) these gaps as shown in FIG. 3.

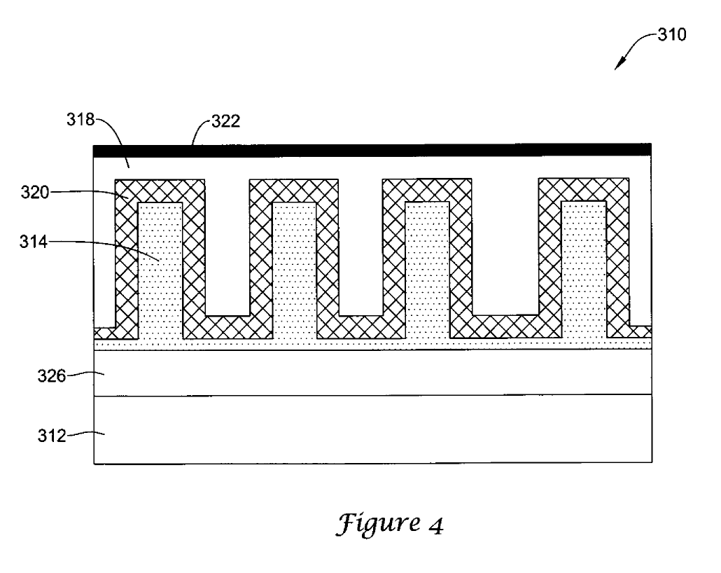

FIG. 4 illustrates another example solar cell 310 that may be similar to other solar cells disclosed herein. Solar cell 310 may include substrate 312, layer 326 coupled to substrate 312, electron conductor layer 314 coupled to layer 326, active layer 320 coupled to electron conductor layer 314, layer 318 coupled to active layer 320, and electrode 322 coupled to layer 318. In some instances, electrode 322 may be the positive electrode (e.g., the cathode). Alternatively, electrode 322 may be the negative electrode (e.g., the anode). As in cells 110/210, substrate 312 may include glass, layer 326 may include fluorine-doped tin oxide glass, electron conductor layer 314 may include TiO₂ or ZnO, active layer 320 may include a blend of poly[2,7-(9,9-di-n-octyl-silafluorene)-alt-5,5″-(4′,7′-di-2-thienyl-2′,1′,3′-benzothiadiazole)] (PSiF-DBT) and PCBM, and layer 318 may include poly(3,4-ethylenedioxythiophene) poly(styrenesulfonate) (PEDOT:PSS). These are only examples. It is contemplated that other materials may be used for these layers including any of those materials disclosed herein.

In cell 310, electron conductor layer 314 may, in some cases, be structured as a nano-pillar, nano-wire, nano-tube or other structured or random array or pattern, and active layer 310 may generally follow the surface of electron conductor layer 314, and layer 318 may “fill in” (partially or fully) the structured arrangement of electron conductor layer 314 and active layer 320 as shown in FIG. 4. This may give active layer 320 a corrugated configuration or shape.

This application may be related to U.S. patent application Ser. No. 12/433,560, entitled “AN ELECTRON COLLECTOR AND ITS APPLICATION IN PHOTOVOLTAICS” and filed Apr. 30, 2009, the entire disclosure of which is incorporated herein by reference. This application may also be related to U.S. patent application Ser. No. 12/423,581, entitled “THIN-FILM PHOTOVOLTAICS” and filed Apr. 14, 2009, the entire disclosure of which is incorporated herein by reference. This application may also be related to U.S. patent application Ser. No. 12/484,034, entitled “QUANTUM DOT SOLAR CELLS” and filed on Jun. 12, 2009, the entire disclosure of which is incorporated herein by reference. This application may also be related to U.S. patent application Ser. No. 12/468,755, entitled “SOLAR CELL WITH ENHANCED EFFICIENCY” and filed May 19, 2009, the entire disclosure of which is incorporated herein by reference. This application may also be related to U.S. patent application Ser. No. 12/614,054, entitled “SOLAR CELL WITH ENHANCED EFFICIENCY” and filed Nov. 6, 2009, the entire disclosure of which is herein incorporated by reference.

It should be understood that this disclosure is, in many respects, only illustrative. Changes may be made in details, particularly in matters of shape, size, and arrangement of steps without exceeding the scope of the invention. The invention's scope, of course, is defined in the language in which the appended claims are expressed.

What is claimed is:

1. A solar cell, comprising:
an first conductor layer forming a pattern of projections on at least one surface with one or more gaps between the projections;
an active layer situated in the gaps between the projections and coupled to the first conductor layer; and
a second conductor layer coupled to the active layer.

2. The solar cell of claim 1, wherein the first conductor layer is an electron conductor layer.

3. The solar cell of claim 2, wherein the second conductor layer is a hole conductor layer.

4. The solar cell of claim 1, wherein the active layer is disposed on and follows a top surface of the pattern of projections.

5. The solar cell of claim 4, wherein the active layer partially fills in the gaps between the projections.

6. The solar cell of claim 5, wherein the second conductor layer partially fills in the gaps between the projections.

7. The solar cell of claim 5, wherein the second conductor fills in the gaps between the projections.

8. The solar cell of claim 4, wherein the active layer fills in the gaps between the projections.

9. The solar cell of claim 1, wherein the active layer includes poly[2,7-(9,9-di-n-octyl-silafluorene)-alt-5,5″-(4′,7′-di-2-thienyl-2′,1′,3′-benzothiadiazole)].

10. The solar cell of claim 1, wherein the active layer includes a polymer blend.

11. The solar cell of claim 10, wherein the active layer includes [6,6]-phenyl-C61-butyric acid methyl ester.

12. The solar cell of claim 1, wherein the second conductor layer includes a conductive polymer.

13. The solar cell of claim 12, wherein the conductive polymer includes:

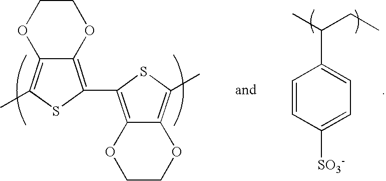

14. A solar cell, comprising:
an electron conductor layer including a pattern of nano-pillars on at least one surface with one or more gaps between the pattern of nano-pillars;
an active layer situated in the gaps between the pattern of nano-pillars and coupled to the electron conductor layer, the active layer not fully filling in the gaps between the pattern of nano-pillars; and
a hole conductor coupled to the active layer.

15. The solar cell of claim 14, wherein the hole conductor does not fully fill in the gaps between the pattern of nano-pillars.

16. The solar cell of claim 14, wherein the hole conductor does fill in the gaps between the pattern of nano-pillars.

17. The solar cell of claim 14, wherein the active layer is disposed on and traces a top surface of the nano-pillars.

18. The solar cell of claim 14, wherein the polymer blend includes [6,6]-phenyl-C61-butyric acid methyl ester.

19. A solar cell, comprising:
an electron conductor layer including pattern of nano-pillars on at least one surface with one or more gaps between the pattern of nano-pillars;
an active layer situated in the gaps between the pattern of nano-pillars and coupled to the electron conductor layer, the active layer filling in the gaps between the pattern of nano-pillars; and
a hole conductor coupled to the active layer.

20. The solar cell of claim 19, wherein the pattern of nano-pillars form a structured or random array or pattern.
